(19) United States
(12) Patent Application Publication
(10) Pub. No.: US 2010/0314247 A1
(43) Pub. Date: Dec. 16, 2010

(54) Filtered cathodic arc device and carbon protective film deposited using the device

(75) Inventors: Shinya Takashima, Tokyo (JP); Masanori Ooto, Tokyo (JP); Yoshiyuki Yonezawa, Matsumoto City (JP)

Correspondence Address: RABIN & Berdo, PC, 1101 14TH STREET, NW, SUITE 500, WASHINGTON, DC, 20005, US

(73) Assignee: Fuji Electric Device Technology Co., Ltd., Tokyo (JP)

(21) Appl. No.: 12/662,832

(22) Filed: May 5, 2010

(30) Foreign Application Priority Data
Jun. 10, 2009 (JP) 2009-139121

(51) Int. Cl. C23C 14/35

(52) U.S. Cl. 204/298.13; 204/298.16

(57) ABSTRACT

A filtered cathodic arc device includes a plasma generating module which generates plasma using an arc discharge which has a cathode target as a deposition raw material; a deposition processing chamber in which a deposition receiving substrate is placed; a curved magnetic field duct that is placed between the plasma generating module and the deposition processing chamber, and that guides plasma generated by the plasma generating module to the deposition processing chamber with a magnetic field; a wool medium formed of a nonmagnetic metal fiber which covers the interior wall of the magnetic field duct; and a bias power source for the wool medium. The device balances reduction of particulate particles and a high deposition rate.

### CROSS-REFERENCE TO RELATED APPLICATION

This non-provisional Application claims the benefit of the priority of Applicants' earlier filed Japanese Patent Application Laid-open No. 2009-139121 filed Jun. 10, 2009, the entire contents of which are incorporated herein by reference.

### BACKGROUND OF THE INVENTION

1. Field of the Invention

The present invention relates to a thin film deposition device using a cathode arc discharge, and to a carbon protective film formed as a hard membrane used in a coating of a slide resistant member or an abrasion resistant member.

2. Description of the Related Art

A diamond-like carbon (DLC) film composed of carbon is used as a hard membrane in a coating for a slide resistant member or an abrasion resistant member. As the DLC film has superior surface smoothness and also has a high hardness, it is appropriate as a surface membrane. Although a sputtering method, a plasma CVD method, and the like, are used as methods of forming this kind of DLC film, in particular, a filtered cathodic arc method has been proposed as a method of depositing a tetrahedral amorphous carbon (ta-C) film with a high hardness (refer to, for example, JP-A-2003-160858).

FIG. 2 is a diagram showing an example of a heretofore known filtered cathodic arc device. The device is configured to include a plasma generating module 1, a magnetic field duct 2, a scanning device 3, and a deposition processing chamber 4. Using a trigger 14, an arc discharge is generated between a target 11 placed in a cathode module 12 and an anode module 13, and plasma including cathodic ions is generated. By guiding the plasma generated with the magnetic field as the plasma passes through the magnetic field duct 2, and reaches a deposition receiving substrate 41, the ions of the target material are deposited on the deposition receiving substrate 41. When depositing a ta-C film, graphite is used as the target material.

Ions, electrons, and neutral atoms emitted from the target raw material are included in the generated plasma. These not only fly at an atomic level, but one portion is also clustered and becomes particulate. These will be called particulate particles. The particulate particles being emitted from the target due to the arc discharge include neutral particulate particles formed of atoms which fly without being ionized, and positively and negatively charged particulate particles. As these particulate particles cause a reduction in film quality and a reduction in smoothness in the event that they are mixed in when depositing an ionized film on the deposition receiving substrate, it is necessary to reduce the number of particulate particles reaching the deposition receiving substrate.

In order to reduce this kind of particulate particle, a structure is used wherein there is a curve in the magnetic field duct between the plasma generating module and processing chamber in which the deposition receiving substrate is held. As the curved magnetic field duct guides only the electrons and cathodic ions, which are charged particles, and does not guide the neutral particles, it is possible to reduce the number of neutral particulate particles reaching the deposition receiving substrate.

Although a large portion of the neutral particles are not guided to the deposition receiving substrate due to using the curved magnetic field duct, it happens that one portion of the neutral particles collides with the interior wall of the magnetic field duct, recoils, and enters the deposition processing chamber. For this reason, neutral particulate particles are mixed in when guiding the ions to the deposition receiving substrate and depositing, the film quality is reduced, and the film smoothness is also reduced.

In order to collect the particles recoiling at the interior wall, it has been proposed to provide various kinds of trapping mechanisms inside the duct. For example, JP-A-2004-244667 proposes a fin-shaped baffle structure, while JP-A-2002-105628 proposes a felt-like porous member. However, when attempting to increase the collection efficiency using a trapping mechanism in order to prevent the mixing in of the particulate particles, it is necessary to lengthen the fins, or to increase the sectional area occupied by the trapping mechanism. As a result, there is a reduction in space through which plasma contributing to the deposition can pass, and one portion of the plasma is blocked by the trapping mechanism, meaning that there may be a reduction in the deposition rate. In order to balance the deposition rate and the increasing of the particle collection efficiency, it is necessary to improve the trapping mechanism without blocking the space through which the plasma is guided.

Also, although the curved magnetic field duct has a certain advantage with respect to the neutral particulate particles, as previously described, positively and negatively charged particulate particles also exist. A further improvement thus is necessary for preventing the mixing in of the positively and negatively charged particulate particles too.

### SUMMARY OF THE INVENTION

In order to solve the heretofore described issues, a filtered cathodic arc device of an aspect of the invention includes a plasma generating module which generates plasma using an arc discharge which has a cathode target as a deposition raw material, a deposition processing chamber in which a deposition receiving substrate is placed, a curved magnetic field duct which, being placed between the plasma generating module and deposition processing chamber, guides plasma generated by the plasma generating module to the deposition processing chamber with a magnetic field, a wool medium formed of a nonmagnetic metal fiber which covers the interior wall of the magnetic field duct, and a bias power source for the wool medium.

It is preferable that the metal fiber of the wool medium is composed of an aluminum alloy, a stainless steel alloy, or copper. Also, it is preferable that the cathode target is comprised of carbon. Also, another aspect of the invention is a carbon protective film deposited using the heretofore described filtered cathodic arc device, wherein the carbon protective film is formed of tetrahedral amorphous carbon.

By covering the interior wall of the curved magnetic field duct with a wool member formed of a nonmagnetic and conductive metal fiber, the trap shape inside the magnetic field duct can easily be made complex, the neutral particle collection efficiency rises, and it is possible to reduce the number of particulate particles reaching the deposition receiving substrate. In addition, by applying a bias voltage to the wool medium, the charged particulate particle collection efficiency rises, and it is possible to reduce the number of particulate particles reaching the deposition receiving substrate.

Furthermore, by applying a bias voltage to the wool member or medium covering the interior wall of the magnetic field duct, a radial electric field is generated inside the magnetic field duct, and it is possible to focus the plasma beam of charged particles in the center of the duct, meaning that, as the plasma beam diameter is restricted, it is guided to the deposition receiving substrate without the plasma being blocked by the trapping mechanism provided on the interior wall of the duct, and thus it is also possible to prevent a reduction of the deposition rate. According to these advantages, it is possible to provide a deposition device which balances an increasing of the particulate particle collection efficiency and a high deposition rate.

Also, by using a filtered cathodic arc device to which the heretofore described improvements are added, and depositing a protective film with carbon as the deposition raw material, it is possible to provide a hard, high quality carbon protective film, with no deterioration of film quality or reduction of smoothness due to the mixing in of particulate particles.

### BRIEF DESCRIPTION OF THE DRAWINGS

FIG. 1 is a device configuration diagram for illustrating one embodiment of a filtered cathodic arc device of the invention; and

FIG. 2 is a configuration diagram of a heretofore known filtered cathodic arc device.

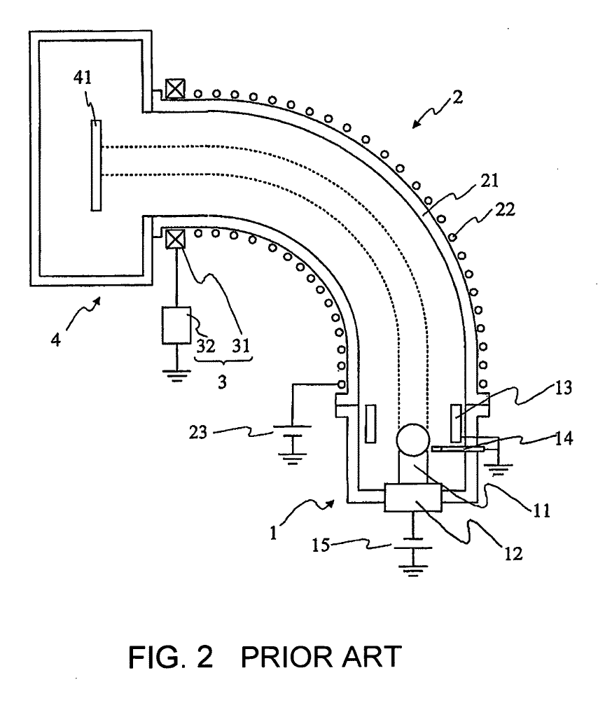

### DETAILED DESCRIPTION OF THE INVENTION

Hereafter, while referring to the drawings, a description will be given of an embodiment of the invention.

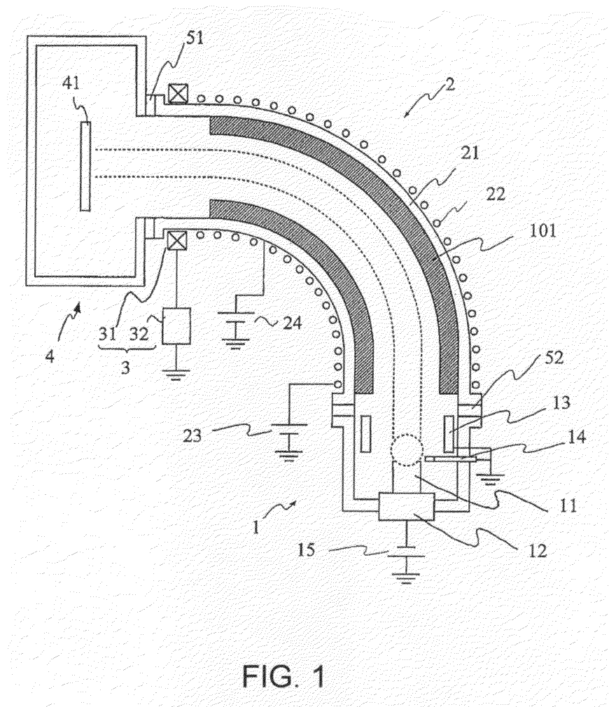

FIG. 1 is a device configuration diagram showing one embodiment of a filtered cathodic arc device of the invention. A deposition device is configured of a plasma generating module 1, a magnetic field duct 2, a scanning device 3, and a processing chamber 4 in which a deposition is carried out. The inside of the deposition device is evacuated to around 1×10⁻⁴ Pa by an evacuating device (not shown).

The plasma generating module 1 includes a target 11, which forms a deposition raw material, a cathode module 12 on which the target 11 is mounted, an anode module 13, which causes an arc discharge to be generated between itself and the target, and a trigger 14 for creating a catalyst for the arc discharge. The target 11 is a material whose deposition is desired and it is possible to use a conductive member such as carbon, titanium, aluminum, tantalum, or tungsten, or an alloy thereof. The cathode module 12 is connected to an arc power source 15, while the anode module 13 and trigger 14 are grounded, and have a ground potential. By causing the trigger 14 to momentarily strike the target 11 in a condition in which an arc voltage is applied to the cathode module 12, it is possible to generate an arc discharge.

The magnetic field duct 2 is configured of a curved cylindrical duct 21, and a magnetic coil 22 provided on the periphery thereof. An exciting current is supplied to the magnetic coil from a magnetic coil power source 23, and a magnetic field is formed along the cylindrical duct 21. The plasma generated by the plasma generating module 1 is guided by the magnetic field along the cylindrical duct 21, passes through the curved cylindrical duct 21, and reaches the deposition processing chamber 4 in which a deposition receiving substrate 41 is placed.

The cylindrical duct 21, being configured of a material which has rigidity, is configured of a material which has conductivity, and which is nonmagnetic. It is possible to use, for example, an aluminum alloy, a stainless steel alloy, or copper.

It is possible to apply a bias voltage to the cylindrical duct 21 using a bias power source 24. The cylindrical duct 21 and deposition processing chamber 4 are connected across an insulating medium 51, and are electrically insulated. Also, since an insulating medium 52 is also disposed between the cylindrical duct 21 and plasma generating module 1, they are electrically insulated.

A wool medium 101 formed of nonmagnetic, conductive metal fiber is placed on the interior wall of the curved cylindrical duct 21 in such a way as to cover the interior wall. By this means, the wall surface structure on the inside of the cylindrical duct 21 is easily made complex, and can be made into a three-dimensionally intricate structure. Also, since the cylindrical duct 21 and wool medium 101 are in contact, a bias voltage may be applied to the wool medium 101 via the cylindrical duct 21. The bias voltage may also be applied directly to the wool medium 101.

Herein, a “wool medium” formed of an assembly of fiber material, refers to a medium wherein a volume filling ratio, which is the percentage of the occupied spatial volume occupied by the fiber material, is 2% or more. The fiber diameter of the metal fiber configuring the wool medium is selected to be 150 μm or less, and preferably, the kind of metal fiber with a small fiber diameter of 50 μm or less is selected as best. In order to effectively apply the bias voltage, it is sufficient that the resistivity of the wool medium is 0.1 Ωcm or less.

As neutral particles emitted from the target 11 by the arc discharge travel straight in the direction in which they are emitted, and do not follow the curve of the magnetic field duct 2, they head toward the interior wall of the duct. By installing the wool medium 101 with its three-dimensionally intricate structure, particle recoil at the cylindrical interior wall is prevented and the neutral particles are collected in the interior of the wool medium 101. Therefore, the neutral particles cannot reach the deposition receiving substrate, resulting in a device which can deposit a high quality film. By using a nonmagnetic material, there is no effect on the magnetic field formed by the magnetic coil wrapped around the periphery of the cylindrical duct. It is possible to use an aluminum alloy, a stainless steel alloy, copper, or the like as the nonmagnetic, conductive metal fiber.

When placing the conductive wool medium in the interior of the duct, space within the interior through which the plasma can pass is reduced but, due to the effect of a radial electric field created by a positive bias voltage applied to the conductive wool medium, positive ions included in a plasma beam guided through the interior of the magnetic field duct are focused in the center of the duct. Consequently, the ions are not blocked by the wool medium and are guided to the processing chamber as a high density beam so that it is possible to realize a high deposition rate. Meanwhile, as the neutral particulate particles are not affected by the electric field, they fly linearly at the same speed and in the same direction as when the arc is discharged. Therefore, it is possible to trap and efficiently collect them in the wool medium provided on the interior wall of the curved cylindrical duct so that the neutral particles are prevented from reaching the deposition receiving substrate.

Apart from positively charged target material ions, which contribute to the deposition, and the neutral particles, negatively charged ions or clusters are also generated during the arc discharge. The negatively charged particles are also a cause of particulate particles. By positively charging the trapping mechanism, the negatively charged particulate particles are adsorbed and collected by electrostatic attractive force, meaning that it is possible to reduce the particulate particles to a greater extent than when not applying a bias voltage. As a result, the device is one which balances collection efficiency and deposition rate, and can deposit a high quality film. When considering only the advantage of adsorbing the negatively charged particles, it is preferable that the voltage applied is on the high side, but in the event that the bias voltage is too high, it becomes impossible to ignore the effect on the electron stream being guided by the magnetic field inside the cylindrical duct, the plasma beam is disrupted, and the deposition rate drops. In order to obtain the advantages of a particle reduction by the absorption of the negatively charged particles, and an increase in the deposition rate by focusing the plasma beam, the setting of the voltage applied is individually carried out in accordance with the device configuration and conditions of use, but is preferably within a range of 5 volts to 100 volts.

The scanning device 3 is configured of two pairs of solenoid coils 31 (only one pair being shown), and a control device 32 which supplies a current to the solenoid coils 31. By applying a deflecting magnetic field to the plasma introduced into the deposition processing chamber 4 with the solenoid coils 31, the beam is deflected vertically with respect to the direction of travel. By this means, even with a deposition receiving substrate which is larger than the diameter of the beam, it is possible to deposit a film over the whole surface.

After carrying out repeated depositions with the device, maintenance can be easily carried out by replacing the wool medium. Consequently, it is possible to prevent the particulate particles accumulating in the wool medium from becoming detached and forming a secondary source of particulate particle generation. In addition, as the wool medium 101 covers the interior wall of the cylindrical duct 21, there is no dirtying of the cylindrical duct 21 so that cleaning is unnecessary and the maintenance of the device itself is simplified.

### Experimental Example 1

Next, a description will be given of an example of an actual deposition using the filtered cathodic arc device of the invention.

In the example, a carbon film is deposited using a graphite target as the target 11, and using a glass disc with a diameter of 65 mm as the deposition receiving substrate 41.

After cleaning the glass disc thoroughly, it is placed in the deposition processing chamber 4, and the interior of the device is evacuated to a vacuum of 1×10⁻⁴ Pa. Under a condition in which −30 volts is applied to the cathode module 12 as the arc voltage, an arc discharge is generated by causing the trigger 14 to momentarily strike against the target 11. The arc current at the time of discharge is taken to be 30 amps.

An exciting current is supplied to the magnetic coil from the magnetic coil power source 23, and a magnetic field of approximately 130 mT is formed along the cylindrical duct 21. A bias voltage of 20 volts is applied to the cylindrical duct 21 by the wool medium bias power source 24.

A wool medium formed of a stainless steel material with an iron content of 70% by weight, a nickel content of 8% by weight, and a chromium content of 18% by weight, with a fiber diameter of 20 μm and a space filling ratio of approximately 10%, is used as the wool medium 101.

As a result of carrying out a five second deposition using the device, a ta-C film with a film thickness of 4.0 nm is obtained. The surface particle density at this time is low at 9.7/cm².

The deposition rates and particulate particle densities separated by particle width are shown in Table 1. Each numerical value is an average value of five deposited discs.

### Comparison Example 1

Using a device the same as that of Experimental Example 1, with the exception of removing the wool medium bias power source 24, a five second deposition is carried out in the same way as in Experimental Example 1. That is, no bias voltage is applied to the cylindrical duct 21. The film thickness of the film obtained being approximately 2.2 nm, the deposition rate drops in comparison with Experimental Example 1. Also, the particle density is 11.5/cm², which is higher than that of Experimental Example 1.

### Comparison Example 2

Using a device the same as that of Experimental Example 1 with the exception of removing the wool medium 101 on the interior wall of the cylindrical duct and the wool medium bias power source 24, a five second deposition is carried out in the same way as in Experimental Example 1. The film thickness of the film obtained is approximately 5 nm, and the deposition rate increases, but the surface particle density is high at 1124.1/cm².

TABLE 1

| | | Particulate Particle Density (no./cm²) | | | | |
|---|---|---|---|---|---|---|
| | | Particle | Particle | Particle | Particle | |
| | | Di- | Di- | Di- | Di- | Par- |
| | Deposition | ameter | ameter | ameter | ameter | ticulate |
| | Rate | 1 μm or | 1 μm to | 3 μm to | 5 μm or | Particle |
| | (nm/s) | less | 3 μm | 5 μm | more | Total |
| Experimental | 0.8 | 1.6 | 5.1 | 2.9 | 0.1 | 9.7 |
| Example 1 | | | | | | |
| Comparison | 0.44 | 2.1 | 5.6 | 3.4 | 0.4 | 11.5 |
| Example 1 | | | | | | |
| Comparison | 1.0 | 203.8 | 580.6 | 309.2 | 30.5 | 1124.1 |
| Example 2 | | | | | | |

### Experimental Example 2

A description will be given of an example wherein a protective film is deposited on a magnetic layer to form a magnetic recording medium.

A glass disc with a diameter of 65 mm is prepared, the glass disc is introduced into a sputtering device after being thoroughly cleaned, and a CoZrNb soft magnetic backing layer, an NiFeCr seed layer, an Ru intermediate layer, and a CoCrPt—SiO₂ granular perpendicular magnetic layer are deposited sequentially.

Apart from placing this in the deposition processing chamber 4 of the filtered cathodic arc device as the deposition receiving substrate 41, and applying −120V to the substrate using a substrate bias power source (not shown), a ta-C film with a film thickness of 2.5 nm is deposited in the same way as in Experimental Example 1. The substrate bias voltage having an advantage of increasing the sp³ bond ratio by increasing the collision energy of the positive ions, it is a mechanism often used in an FCVA device.

As the ta-C film obtained is a film with high hardness, which does not include hydrogen, which has a high sp³ bond ratio of 85% based on a waveform separation of a C1s spectrum obtained by XPS measurement shows, and which has little particulate particle contamination, it can be used as a protective film with superior slide resistance and corrosion resistance when compared with other protective films, an a-C film using a heretofore known sputtering device, or an a-C:H film using a CVD device, and it is possible to increase the reliability of the magnetic recording medium.

The ta-C film obtained according to the invention being a hard, high quality thin film with little particle contamination, apart from a protective film of a magnetic recording medium, it is also appropriate as a protective film of a slide resistant member or an abrasion resistant member.

While the present invention has been described in conjunction with embodiments and variations thereof, one of ordinary skill, after reviewing the foregoing specification, will be able to effect various changes, substitutions of equivalents and other alterations without departing from the broad concepts disclosed herein. It is therefore intended that Letters Patent granted hereon be limited only by the definition contained in the appended claims and equivalents thereof.

What is claimed is:

1. A filtered cathodic arc device, comprising:
a plasma generating module which generates plasma using an arc discharge which has a cathode target as a deposition raw material;
a deposition processing chamber in which a deposition receiving substrate is placed;
a curved magnetic field duct that is placed between the plasma generating module and the deposition processing chamber, and that guides plasma generated by the plasma generating module to the deposition processing chamber with a magnetic field;
a wool medium formed of a nonmagnetic metal fiber which covers the interior wall of the magnetic field duct; and
a bias power source for the wool medium.

2. The filtered cathodic arc device according to claim 1, wherein the metal fiber of the wool medium is composed of a material selected from the group consisting of an aluminum alloy, a stainless steel alloy, and copper.

3. The filtered cathodic arc device according to claim 1, wherein the cathode target is comprised of carbon.

4. A carbon protective film deposited using the filtered cathodic arc device according to claim 3, wherein the carbon protective film is composed of tetrahedral amorphous carbon.
